(19) United States
(12) Patent Application Publication
(10) Pub. No.: US 2025/0255108 A1
(43) Pub. Date: Aug. 7, 2025

(54) DISPLAY DEVICE

(71) Applicant: Samsung Display Co., LTD., Yongin-si (KR)

(72) Inventors: Dong Min LEE, Yongin-si (KR); Joon Yong PARK, Yongin-si (KR); Hyun Eok SHIN, Yongin-si (KR); Su Kyoung YANG, Yongin-si (KR)

(21) Appl. No.: 18/907,809

(22) Filed: Oct. 7, 2024

(30) Foreign Application Priority Data
Feb. 6, 2024 (KR) 10-2024-0017938

(51) Int. Cl. H10K 59/122

(52) U.S. Cl. CPC H10K 59/122

(57) ABSTRACT

A display device is provided. The display device includes a pixel electrode disposed on a substrate; a pixel-defining layer disposed on the substrate and exposing the pixel electrode; an emissive layer disposed on the pixel electrode; a common electrode disposed on the emissive layer; a first bank disposed on the pixel-defining layer; and a second bank disposed on the first bank and including a side surface protruding more than a side surface of the first bank, wherein the second bank contains titanium-zinc (TiZn).

This application claims priority to Korean Patent Application No. 10-2024-0017938, filed on Feb. 6, 2024, and all the benefits accruing therefrom under 35 U.S.C. § 119, the content of which in its entirety is herein incorporated by reference.

### BACKGROUND

### Field

The present disclosure relates to a display device.

### Description of the Related Art

As the information-oriented society evolves, various demands for display devices are ever increasing. For example, display devices are being employed in a variety of electronic devices such as, for example, smart phones, digital cameras, laptop computers, navigation devices, and smart televisions. Display devices may be flat-panel display devices such as, for example, a liquid-crystal display device, a field emission display device, and an organic light-emitting display device. Among such flat panel display devices, a light-emitting display device includes a light-emitting element that can emit light on its own, such that each of the pixels of the display panel can emit light by themselves. Accordingly, a light-emitting display device can display images without a backlight unit that supplies light to the display panel.

Recently, display devices are being employed in devices in the form of glasses for providing virtual reality and augmented reality. In some cases in which a display device is applied to devices in the form of glasses, the display device may be a very small size of 2 inches or less with a high pixel integration to achieve high resolution. For example, the display device may have a high pixel integration of 400 PPI (pixels per inch) or higher.

### SUMMARY

Aspects of the present disclosure provide a display device including separated light-emitting elements which have been formed in small emission areas without a mask process.

Aspects of the present disclosure also provide a display device with high luminous efficiency, with no dark spots in pixels.

It should be noted that objects of the present disclosure are not limited to the above-mentioned object; and other objects of the present disclosure will be apparent to those skilled in the art from the following descriptions.

According to an embodiment of the present disclosure, a display device includes a pixel electrode disposed on a substrate; a pixel-defining layer disposed on the substrate and exposing the pixel electrode; an emissive layer disposed on the pixel electrode; a common electrode disposed on the emissive layer; a first bank disposed on the pixel-defining layer; and a second bank disposed on the first bank and including a side surface protruding more than a side surface of the first bank, wherein the second bank contains titanium-zinc (TiZn). The second bank may be amorphous.

A roughness of the second bank may be equal to or less than 1 nm.

A peak width of the second bank may be 7° or more in an X-ray diffraction spectroscopy (XRD) spectrum.

The second bank may include a metal layer disposed on the first bank and containing titanium-zinc (TiZn); and a metal oxide layer disposed on the metal layer.

The metal oxide layer may include an oxide of titanium-zinc (TiZn).

A thickness of the metal oxide layer may range from 1% to 10% of an overall thickness of the second bank.

The thickness of the metal oxide layer of the second bank may be constant.

A thickness of the second bank may range from 500 Å to 1,500 Å.

A ratio of zinc (Zn) relative to a total number of atoms in the metal layer of the second bank may range from 20 at % to 60 at %.

The display device may further include a residual pattern disposed between the first pixel electrode and the pixel-defining layer.

The display device may further include a lower inorganic encapsulation layer disposed on the common electrode and the second bank and spaced apart from an upper surface of the second bank.

The display device may further include an organic encapsulation layer disposed between the upper surface of the second bank and the lower inorganic encapsulation layer.

An end of the common electrode is in contact with the side surface of the first bank, and an opposite end of the common electrode is in contact with another side surface of the first bank.

According to an embodiment of the present disclosure, a display device includes a pixel electrode disposed on a substrate; a pixel-defining layer disposed on the substrate and exposing the pixel electrode; an emissive layer disposed on the pixel electrode; a common electrode disposed on the emissive layer; a first bank disposed on the pixel-defining layer; and a second bank disposed on the first bank and including a side surface protruding more than a side surface of the first bank, wherein in an X-ray diffraction spectroscopy (XRD) spectrum, the second bank has one or two peaks in a 2θ (2theta) range from 0° to 80°.

A peak width associated with the second bank is 7° or more in an X-ray diffraction spectroscopy (XRD) spectrum.

A roughness of the second bank is equal to or less than 1 nm.

According to an embodiment of the present disclosure, a display device includes a pixel electrode disposed on a substrate; a pixel-defining layer disposed on the substrate and exposing the pixel electrode; an emissive layer disposed on the pixel electrode; a common electrode disposed on the emissive layer; a first bank disposed on the pixel-defining layer; and a second bank disposed on the first bank and including a side surface protruding more than a side surface of the first bank, wherein the second bank includes a metal layer disposed on the first bank and containing titanium-zinc (TiZn), and a metal oxide layer disposed on the metal layer and containing an oxide of titanium-zinc (TiZn), and wherein a thickness of the metal oxide layer ranges from 1% to 10% of a total thickness of the second bank.

The total thickness of the second bank may range from 500 Å to 1,500 Å.

A ratio of zinc (Zn) relative to a total number of atoms in the metal layer of the second bank may range from 20 at % to 60 at %.

According to an embodiment of the present disclosure, dark spots may be eliminated in pixels in a display device, and Mura may be prevented in the display panel.

It should be noted that effects of the present disclosure are not limited to those described herein and other effects of the present disclosure will be apparent to those skilled in the art from the following descriptions.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view of a display device according to an embodiment of the present disclosure.

FIG. 2 is a cross-sectional view of the display device of FIG. 1 seen from the side.

FIG. 3 is a plan view illustrating arrangements of emission areas in a display area of a display device according to an embodiment.

FIG. 4 is a cross-sectional view illustrating a part of a display device according to an embodiment of the present disclosure.

FIG. 5 is an enlarged view of area A1 of FIG. 4.

FIG. 6 is an enlarged view of area A2 in FIG. 5.

FIG. 7 is an enlarged cross-sectional view of a second bank containing crystalline titanium.

FIG. 8 is a view illustrating the second bank containing crystalline titanium using a scanning probe microscope (AFM).

FIG. 9 is a graph illustrating the second bank containing crystalline titanium observed using X-ray diffraction spectroscopy (XRD).

FIG. 10 is an image illustrating an example where the second bank containing crystalline titanium was not removed from the emission areas, observed using a scanning electron microscope (SEM).

FIG. 11 is a view illustrating the second bank according to an embodiment of the present disclosure, observed using a scanning probe microscope (AFM).

FIG. 12 is a graph illustrating the second bank of the display device according to the embodiment, observed using X-ray diffraction spectroscopy (XRD).

### DETAILED DESCRIPTION

The invention will now be described more fully hereinafter with reference to the accompanying drawings, in which example embodiments of the invention are illustrated. Aspects supported by the present disclosure may, however, be embodied in different forms and should not be construed as limited to the embodiments set forth herein. Rather, the example embodiments are provided such that this disclosure will be thorough and complete, and will fully convey the scope of example aspects of the present disclosure to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” and the like may be used herein to describe various elements, these elements should not be limited by these terms. These terms are used to distinguish one element from another element. For instance, a first element discussed below could be termed a second element without departing from the teachings of the invention. Similarly, the second element could also be termed the first element.

The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within +30%, 20%, 10%, 5% of the stated value, for example.

Hereinafter, embodiments will be described with reference to the accompanying drawings.

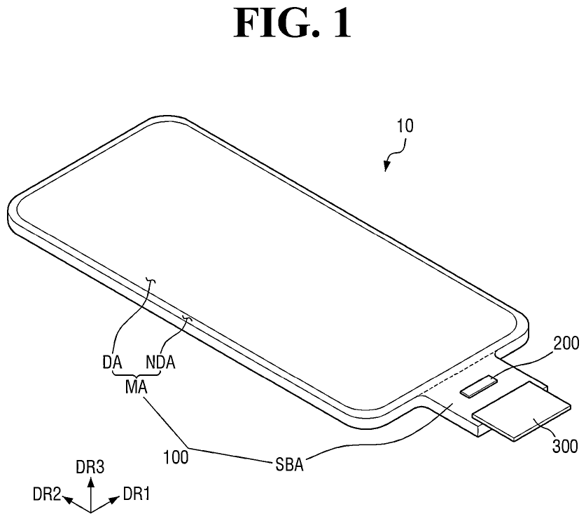

FIG. 1 is a perspective view of a display device according to an embodiment of the present disclosure.

Referring to FIG. 1, a display device 10 according to the embodiment may be included in an electronic device and provide a display screen of the electronic device. The electronic device may refer to any electronic device that provides a display screen. For example, the electronic device may include a television set, a laptop computer, a monitor, an electronic billboard, the Internet of Things devices, a mobile phone, a smart phone, a tablet personal computer (PC), an electronic watch, a smart glass, a smart watch, a watch phone, a head-mounted display device, a mobile communications terminal, an electronic notebook, an electronic book, a portable multimedia player (PMP), a navigation device, a game console and a digital camera, a camcorder, and the like.

The shape of the display device 10 may be modified in a variety of ways. For example, the display device 10 may have a shape similar to a rectangle having shorter sides in the first direction DR1 and longer sides in the second direction DR2. The corners where the shorter sides in the first direction DR1 meet the longer sides in the second direction DR2 may be rounded with a predetermined curvature. It should be understood, however, that embodiments of the present disclosure are not limited thereto. The corners may be formed at a right angle. The shape of the display device 10 when viewed from the top is not limited to a quadrangular shape, but may be formed in a shape similar to other polygonal shapes, a circular shape, or an elliptical shape.

The display device 10 may include a display panel 100, a display driver 200, a circuit board 300 and a touch driver 400.

The display panel 100 may include a main area MA and a subsidiary area SBA.

The main area MA may include the display area DA including pixels for displaying images, and the non-display area NDA located around the display area DA. The display area DA may output light from a plurality of emission areas or a plurality of open areas. For example, the display panel 100 may include a pixel circuit including switching elements, a pixel-defining layer that defines the emission areas or the open areas, and self-light-emitting elements.

For example, the self-light-emitting element may include, but is not limited to, at least one of: an organic light-emitting diode including an organic emissive layer, a quantum-dot light-emitting diode (quantum LED) including a quantum-dot emissive layer, an inorganic light-emitting diode (inorganic LED) including an inorganic semiconductor, and a micro light-emitting diode (micro LED).

A plurality of pixels, a plurality of scan lines, a plurality of data lines, and a plurality of voltage lines may be arranged in the display area DA. Each of the plurality of pixels may be defined as the minimum unit that emits light, and each of the above-described self-luminous elements may work as a pixel. The plurality of scan lines may supply scan signals received from a scan driver to a plurality of pixels. The plurality of data lines may supply data voltages received from the display driver 200 to a plurality of pixels. The plurality of voltage lines may provide supply voltages received from the display driver 200 to a plurality of pixels.

The non-display area NDA may be located on the outer side of the display area DA. The non-display area NDA may be defined as the edge of the main area MA of the display panel 100. The non-display area NDA may include a scan driver that supplies scan signals to scan lines, and fan-out lines that connect the display driver 200 with the display area DA.

The subsidiary area SBA may be extended from one side of the main area MA. The subsidiary area SUB may include a flexible material that can be bent, folded, or rolled. In an example in which the subsidiary area SBA is bent, the subsidiary area SBA may overlap the main area MA in the thickness direction (third direction DR3). The subsidiary area SBA may include pads connected to the display driver 200 and the circuit board 300. According to another embodiment, the subsidiary area SBA may be eliminated, and the display driver 200 and the pads may be disposed in the non-display area NDA.

The display driver 200 may output signals and voltages for driving the display panel 100. The display driver 200 may supply data voltages to data lines. The display driver 200 may apply a supply voltage to a power line, and may supply a scan control signal to the scan driver. The display driver 200 may be implemented as an integrated circuit (IC) and may be attached on the display panel 100 by a chip-on-glass (COG) technique, a chip-on-plastic (COP) technique, or ultrasonic bonding. For example, the display driver 200 may be disposed in the subsidiary area SBA and may overlap with the main area MA in the thickness direction (third direction DR3) as the subsidiary area SBA is bent. In another example, the display driver 200 may be mounted on the circuit board 300.

The circuit board 300 may be attached on the pad area of the display panel 100 using an anisotropic conductive film (ACF). Lead lines of the circuit board 300 may be electrically connected to the pads of the display panel 100. The circuit board 300 may be a flexible printed circuit board (FPCB), a printed circuit board (PCB), or a flexible film such as, for example, a chip-on-film (COF).

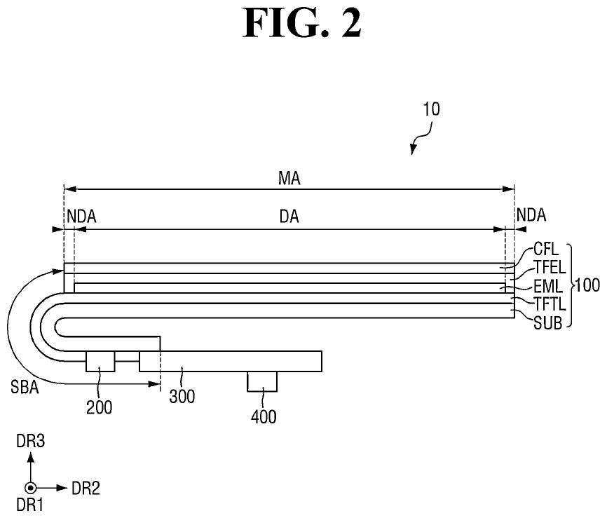

FIG. 2 is a cross-sectional view of the display device of FIG. 1 seen from the side. Specifically, FIG. 2 illustrates the display device in FIG. 1 when the display device is folded.

Referring to FIG. 2, the display panel 100 may include a substrate SUB, a thin-film transistor layer TFTL, an emission material layer EML, a thin-film encapsulation layer TFEL, and a color filter layer CFL.

The substrate SUB may be a base substrate or a base member. The substrate SUB may be a flexible substrate that can be bent, folded, or rolled. For example, the substrate SUB may include, but is not limited to, a polymer resin such as, for example, polyimide PI. According to another embodiment, the substrate SUB may include a glass material or a metal material.

The thin-film transistor layer TFTL may be disposed on the substrate SUB. The thin-film transistor layer TFTL may include a plurality of thin-film transistors forming pixel circuits of pixels. The thin-film transistor layer TFTL may further include scan lines, data lines, voltage lines, scan control lines, fan-out lines for connecting the display driver 200 with the data lines, lead lines for connecting the display driver 200 with the pads, and other components. Each of the thin-film transistors may include a semiconductor region, a source electrode, a drain electrode, and a gate electrode. In an example in which the scan driver is formed on one side of the non-display area NDA of the display panel 100, the scan driver may include thin-film transistors.

The thin-film transistor layer TFTL may be disposed in the display area DA, the non-display area NDA and the subsidiary area SBA. The thin-film transistors in the pixels, the scan lines, the data lines, and the power supply lines on the thin-film film transistor layer TFTL may be disposed in the display area DA. The scan control lines and the fan-out lines in the thin-film transistor layer TFTL may be disposed in the non-display area NDA. The lead lines of the thin-film transistor layer TFTL may be disposed in the subsidiary area SBA.

The emission material layer EML may be disposed on the thin-film transistor layer TFTL. The emission material layer EML may include a plurality of light-emitting elements each including a first electrode, a second electrode and an emissive layer to emit light, and a pixel-defining layer for defining the pixels. The plurality of light-emitting elements in the emission material layer EML may be disposed in the display area DA.

According to an embodiment of the present disclosure, the emissive layer may be an organic emissive layer containing an organic material. The emissive layer may include a hole transporting layer, an organic light-emitting layer and an electron transporting layer. In an example in which the first electrode receives a voltage and the second electrode receives a cathode voltage through the thin-film transistors on the thin-film transistor layer TFTL, the holes and electrons may move to the organic light-emitting layer through the hole transporting layer and the electron transporting layer, respectively, such that they combine in the organic light-emitting layer to emit light.

According to another embodiment, the light-emitting elements may include quantum-dot light-emitting diodes each including a quantum-dot emissive layer, inorganic light-emitting diodes each including an inorganic semiconductor, or micro light-emitting diodes.

The thin-film encapsulation layer TFEL may cover the upper and side surfaces of the emission material layer EML, and can protect the emission material layer EML. The thin-film encapsulation layer TFEL may include at least one inorganic layer and at least one organic layer for encapsulating the emission material layer EML.

The color filter layer CFL may be disposed on the thin-film encapsulation layer TFEL. The color filter layer CFL may include a plurality of color filters associated with the plurality of emission areas, respectively. Each of the color filters may selectively transmit light of a particular wavelength and block or absorb light of other wavelengths. The color filter layer CFL may absorb some of light introduced from the outside of the display device 10 to reduce the reflection of external light. Accordingly, the color filter layer CFL can prevent distortion of colors due to the reflection of external light.

Since the color filter layer CFL is disposed directly on the thin-film encapsulation layer TFEL, the display device 10 may be implemented without a separate substrate for the color filter layer CFL. Therefore, the thickness of the display device 10 can be relatively small.

In some embodiments, the display device 10 may further include an optical device. An optical device can emit or receive light in the infrared, ultraviolet and visible ranges. For example, the optical device may be an optical sensor that senses light incident on the display device 10, such as, for example, a proximity sensor, an illuminance sensor, a camera sensor, a finger sensor and an image sensor.

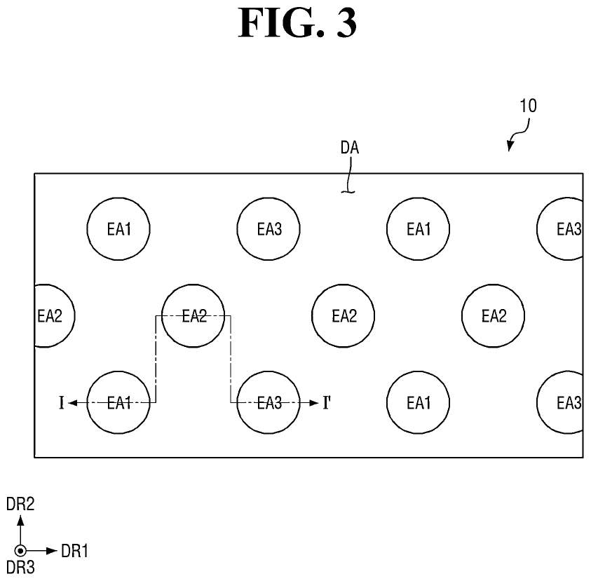

FIG. 3 is a plan view illustrating a part of the display device according to the embodiment of the present disclosure. FIG. 3 is a plan view illustrating a layout of emission areas EA1, EA2 and EA3 in the display area DA of the display device 10.

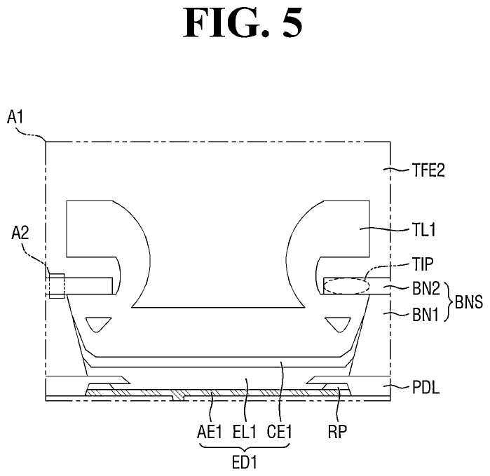

Referring to FIG. 3, the display device 10 may include a plurality of emission areas EA1, EA2 and EA3 arranged in the display area DA. The emission areas EA1, EA2 and EA3 may include a first emission area EA1, a second emission area EA2 and a third emission area EA3 that emit light of different colors. The first to third emission areas EA1, EA2 and EA3 may emit red, green and blue light, respectively. The colors of light emitted from the emission areas EA1, EA2 and EA3 may vary based on the type of light-emitting elements ED1, ED2 and ED3 (see FIG. 5), which will be described later. For example, the first emission area EA1 may output first light, the second emission area EA2 may output second light, and the third emission area EA3 may output third light. It is, however, to be understood that embodiments of the present disclosure are not limited thereto.

The emission areas EA1, EA2 and EA3 may be arranged in a PenTile™ matrix, for example, a diamond PenTile™ matrix. For example, the first emission area EA1 and the third emission area EA3 are spaced apart from each other in the first direction DR1, and may be arranged alternately in the first direction DR1 and the second direction DR2. The second emission area EA2 may be spaced apart from another adjacent second emission area EA2 in the first direction DR1 and the second direction DR2. The second emission area EA2 and the first emission area EA1, or the second emission area EA2 and the third emission area EA3 may be arranged alternately in a direction in the plane formed by the first direction DR1 and the second direction DR2.

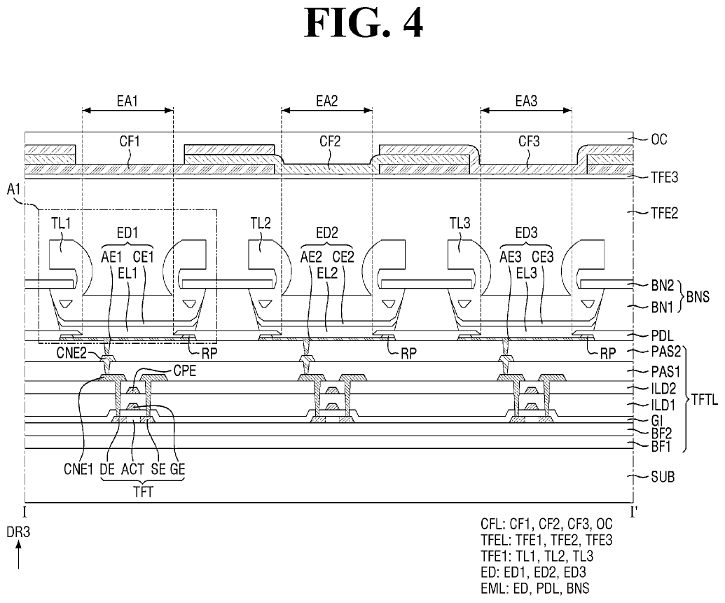

Each of the first to third emission areas EA1, EA2 and EA3 may be defined by a pixel-defining layer PDL (see FIG. 4), which will be described later.

FIG. 4 is a cross-sectional view illustrating a part of the display device according to the embodiment of the present disclosure. Specifically, FIG. 4 is a cross-sectional view taken along line I-I′ of FIG. 3, illustrating the cross sections of the substrate SUB, the thin-film transistor layer TFTL, the emission material layer EML, the thin-film encapsulation layer TFEL, and the color filter layer CFL.

The thin-film transistor layer TFTL may include a first buffer layer BF1, a bottom metal layer (not illustrated), a second buffer layer BF2, a thin-film transistor TFT, a gate insulator GI, a first interlayer dielectric layer ILD1, a capacitor electrode CPE, a second interlayer dielectric layer ILD2, a first connection electrode CNE1, a first passivation layer PAS1, a second connection electrode CNE2 and a second passivation layer PAS2.

The first buffer layer BF1 may be disposed on the substrate SUB. The first buffer layer BF1 may include an inorganic film capable of preventing permeation of air or moisture. For example, the first buffer layer BF1 may include a plurality of inorganic films stacked on one another alternately.

The bottom metal layer (not illustrated) may be disposed on the first buffer layer BF1. For example, the bottom metal layer may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The second buffer layer BF2 may cover the first buffer layer BF1 and the bottom metal layer. The second buffer layer BF2 may include an inorganic film that can prevent permeation of air or moisture. For example, the second buffer layer BF2 may include a plurality of inorganic films stacked on one another alternately.

The thin-film transistor TFT may be disposed on the second buffer layer BF2 and may form a pixel circuit of each of a plurality of pixels. For example, the thin-film transistor TFT may be a driving transistor or a switching transistor of the pixel circuit. The thin-film transistor TFT may include a semiconductor layer ACT, a source electrode SE, a drain electrode DE and a gate electrode GE.

The semiconductor layer ACT may be disposed on the second buffer layer BF2. The semiconductor layer ACT may overlap the bottom metal layer and a gate electrode GE in the thickness direction DR3 and may be insulated from the gate electrode GE by the gate insulator GI. The material of a part of the semiconductor layer ACT may be made conductive to form the source electrode SE and the drain electrode DE.

The gate electrode GE may be disposed on the gate insulator GI. The gate electrode GE may overlap the semiconductor layer ACT in the thickness direction DR3 with the gate insulator GI interposed between the gate electrode GE and the semiconductor layer ACT.

The gate insulator GI may be disposed on the semiconductor layer ACT. For example, the gate insulator GI may cover the semiconductor layer ACT and the second buffer layer BF2, and may insulate the semiconductor layer ACT from the gate electrode GE. The gate insulator GI may include a contact hole through which the first connection electrode CNE1 passes.

The first interlayer dielectric layer ILD1 may cover the gate electrode GE and the gate insulator GI. The first interlayer dielectric layer ILD1 may include a contact hole through which the first connection electrode CNE1 passes. The contact holes of the first interlayer dielectric layer ILD1 may be connected to the contact holes of the gate insulator GI and the contact holes of the second interlayer dielectric layer ILD2.

The capacitor electrode CPE may be disposed on the first interlayer dielectric layer ILD1. The capacitor electrode CPE may overlap with the gate electrode GE in the thickness direction DR3. The capacitor electrode CPE and the gate electrode GE may form a capacitance.

The second interlayer dielectric layer ILD2 may cover the capacitor electrode CPE and the first interlayer dielectric layer ILD1. The second interlayer dielectric layer ILD2 may include a contact hole through which the first connection electrode CNE1 passes. The contact hole of the second interlayer dielectric layer ILD2 may be connected to the contact hole of the first interlayer dielectric layer ILD1 and the contact hole of the gate insulator GI.

The first connection electrode CNE1 may be disposed on the second interlayer dielectric layer ILD2. The first connection electrode CNE1 may electrically connect the drain electrode DE of the thin-film transistor TFT with the second connection electrode CNE2. The first connection electrode CNE1 may be inserted into a contact hole formed in the second interlayer dielectric layer ILD2, the first interlayer dielectric layer ILD1, and the gate insulator GI to be in contact with the drain electrode DE of the thin-film transistor TFT.

The first passivation layer PAS1 may cover the first connection electrode CNE1 and the second interlayer dielectric layer ILD2. The first passivation layer PAS1 can protect the thin-film transistor TFT. The first passivation layer PAS1 may include a contact hole through which the second connection electrode CNE2 passes.

The second connection electrode CNE2 may be disposed on the first passivation layer PAS1. The second connection electrode CNE2 may electrically connect the first connection electrode CNE1 with pixel electrodes AE1, AE2 and AE3 of light-emitting elements ED. The second connection electrode CNE2 may be inserted into a contact hole formed in the first passivation layer PAS1 to be in contact with the first connection electrode CNE1.

The second passivation layer PAS2 may cover the second connection electrode CNE2 and the first passivation layer PAS1. The second passivation PAS2 may include contact holes through which the pixel electrodes AE1, AE2 and AE3 of the light-emitting elements ED pass.

The emission material layer EML may be disposed on the thin-film transistor layer TFTL. The emission material layer EML may include light-emitting elements ED, the pixel-defining layer PDL and a bank structure BNS. The light-emitting elements ED may include the pixel electrodes AE1, AE2 and AE3, emissive layers EL1, EL2 and EL3, and common electrodes CE1, CE2 and CE3, respectively.

FIG. 5 is an enlarged view illustrating the first emission area of FIG. 4, specifically area A1.

Referring to FIG. 5 in conjunction with FIGS. 3 through 5, the display device 10 may include a plurality of emission areas EA1, EA2 and EA3 arranged in the display area DA. The emission areas EA1, EA2 and EA3 may be defined as areas where the pixel electrodes AE1, AE2 and AE3, the emissive layers EL1, EL2 and EL3, and the common electrodes CE1, CE2 and CE3 overlap one another in the thickness direction of the substrate SUB. The emission areas EA1, EA2 and EA3 may include areas where light is output from the light-emitting elements ED1, ED2 and ED3 and passes through the color filter layer CFL in the third direction DR3, in which the pixel electrodes AE1, AE2 and AE3, the emissive layers EL1, EL2 and EL3, and the common electrodes CE1, CE2 and CE3 are sequentially stacked on one another. The emission areas EA1, EA2 and EA3 may include a first emission area EA1, a second emission area EA2 and a third emission area EA3 that are spaced apart from one another and emit light of the same color of different colors.

According to an embodiment of the present disclosure, the first to third emission areas EA1, EA2 and EA3 may have the same area or size. For example, the first emission area EA1, the second emission area EA2 and the third emission area EA3 of the display device 10 may have the same area. It is, however, to be understood that embodiments of the present disclosure are not limited thereto. The first to third emission areas EA1, EA2 and EA3 of the display device 10 may have different areas or sizes. For example, the area of the second emission area EA2 may be larger than the areas of the first emission area EA1 and the third emission area EA3, and the area of the third emission area EA3 may be larger than the area of the first emission area EA1. The intensity of light respectively emitted from the emission areas EA1, EA2 and EA3 may vary based on the size of the emission areas EA1, EA2 and EA3. The colors of the images displayed on the display device 10 can be controlled by adjusting the size of the emission areas EA1, EA2 and EA3. Although the emission areas EA1, EA2 and EA3 have the same area according to the embodiment of FIG. 4, embodiments of the present disclosure are not limited thereto.

In the display device 10, one first emission area EA1, one second emission areas EA2 and one third emission area EA3 disposed adjacent to one another may form a single pixel group. A single pixel group may represent black-and-white or grayscales by including the emission areas EA1, EA2 and EA3 emitting light of different colors. It should be understood, however, that embodiments of the present disclosure are not limited thereto. The combination of the emission areas EA1, EA2, and EA3 forming a single pixel group may be modified based on the arrangement of the emission areas EA1, EA2 and EA3, and the colors of the light emitted from them.

The display device 10 may include a plurality of light-emitting elements ED1, ED2 and ED3 disposed in different emission areas EA1, EA2 and EA3. The light-emitting elements ED1, ED2 and ED3 may include a first light-emitting element ED1 disposed in the first emission area EA1, a second light-emitting element ED2 disposed in the second emission area EA2, and a third light-emitting element ED3 disposed in the third emission area EA3.

The light-emitting elements ED1, ED2 and ED3 may include pixel electrodes AE1, AE2 and AE3, emissive layers EL1, EL2 and EL3, and common electrodes CE1, CE2 and CE3, respectively. The light-emitting elements ED1, ED2 and ED3 disposed in different emission areas EA1, EA2 and EA3 may emit light of different colors based on the materials of the emissive layers EL1, EL2 and EL3. For example, the first light-emitting element ED1 disposed in the first emission area EA1 may emit red light with a peak wavelength ranging from 610 nanometer (nm) to 650 nm, the second light-emitting element ED2 disposed in the second emission area EA2 may emit green light with a peak wavelength ranging from 510 nm to 550 nm, and the third light-emitting element ED3 disposed in the third emission area EA3 may emit blue light with a peak wavelength ranging from 440 nm to 480 nm. The first to third emission areas EA1, EA2 and EA3 forming a single pixel may include the light-emitting elements ED1, ED2 and ED3 emitting light of different colors to represent black-and-white or grayscale images. Alternatively, the emissive layers EL1, EL2 and EL3 may include two or more materials that emit light of different colors, such that one emissive layer may emit mixed light. For example, the emissive layers EL1, EL2 and EL3 may contain a material emitting red light as well as a material emitting green light to emit yellow light, or may contain all of a material emitting red light, a material emitting green light, and a material emitting blue light to emit white light.

The pixel electrodes AE1, AE2 and AE3 may be disposed on the second passivation layer PAS2. The pixel electrodes AE1, AE2 and AE3 may be disposed in the emission areas EA1, EA2 and EA3, respectively. The pixel electrodes AE1, AE2 and AE3 may include a first pixel electrode PE1 disposed in the first emission area EA1, the second pixel electrode PE2 disposed in the second emission area EA2, and the third pixel electrode PE3 disposed in the third emission area EA3. The first pixel electrode AE1, the second pixel electrode AE2 and the third pixel electrode AE3 may be spaced apart from one another on the second passivation layer PAS2.

The pixel electrodes AE1, AE2 and AE3 may be electrically connected to the drain electrode DE of the thin-film transistor TFT through the first and second connection electrodes CNE1 and CNE2. Edges of the s pixel electrodes AE1, AE, and AE3 spaced apart from one another may be covered by the pixel-defining layer PDL, and thus the first to third pixel electrodes AE1, AE2 and AE3 may be insulated from one another.

The pixel electrodes AE1, AE2 and AE3 may include a transparent electrode material or/and a conductive metal material, and may have a single-layer or multi-layer structure. The metal material may be one or more of silver (Ag), copper (Cu), aluminum (Al), nickel (Ni), lanthanum (La), titanium (Ti), and titanium nitride (TiN). The transparent electrode material may be one or more of indium tin oxide (ITO), indium zinc oxide (IZO), and indium tin zinc oxide (ITZO).

The pixel-defining layer PDL may be disposed on the second passivation layer PAS2, the residual pattern RP and the pixel electrodes AE1, AE2 and AE3. The pixel-defining layer PDL may be disposed entirely on the second passivation layer PAS2. The pixel-defining layer PDL may cover the side surfaces of the pixel electrodes AE1, AE2 and AE3 and the residual pattern RP such that the pixel-defining layer PDL exposes parts of the upper surfaces of the pixel electrodes AE1, AE2 and AE3. For example, the pixel-defining layer PDL may expose the first pixel electrode AE1 in the first emission area EA1, and the first emissive layer EL1 may be disposed directly on the first pixel electrode AE1.

The pixel-defining layer PDL may include an inorganic insulating material. The pixel-defining layer PDL may include, but is not limited to, at least one of: a silicon nitride layer, a silicon oxynitride layer, a silicon oxide layer, a titanium oxide layer, an aluminum oxide layer, tantalum oxide, hafnium oxide, zinc oxide, and an amorphous silicon layer.

According to an embodiment, the pixel-defining layer PDL may be disposed on the pixel electrodes AE1, AE2 and AE3 and may be spaced apart from upper surfaces of the pixel electrodes AE1, AE2 and AE3. The pixel-defining layer PDL may partially overlap with the upper surfaces of the pixel electrodes AE1, AE2 and AE3 in the thickness direction DR3 of the substrate SUB but not be in direct contact with them. The residual pattern RP may be disposed between the lower surface of the pixel-defining layer PDL and the upper surfaces of the pixel electrodes AE1, AE2 and AE3. It should be noted that the pixel-defining layer PDL may be in direct contact with the side surfaces of the pixel electrodes AE1, AE2 and AE3. The side surfaces of the pixel-defining layer PDL may protrude toward the emission areas EA1, EA2 and EA3 rather than the side surfaces of the second bank BN2.

The residual pattern RP may be disposed on the edges of each of the first to third pixel electrodes AE1, AE2 and AE3. The pixel-defining layer PDL may not be in direct contact with the upper surfaces of the pixel electrodes AE1, AE2 and AE3 thanks to the residual pattern RP. The residual pattern RP may include a metal or oxide semiconductor material. Although the side surfaces of the residual pattern RP facing the emission areas EA1, EA2 and EA3 are more depressed than the side surfaces of the pixel-defining layer PDL in the example illustrated in the drawing, embodiments of the present disclosure are not limited thereto. The side surface of the residual pattern RP may protrude from the side surface of the pixel-defining layer PDL toward the emission areas EA1, EA2 and EA3, or may be aligned with the side surface of the pixel-defining layer PDL. The side surface of the pixel-defining layer PDL may be the side surface located at the outermost position toward the emission areas EA1, EA2 and EA3.

The emissive layers EL1, EL2 and EL3 may be disposed on the pixel electrodes AE1, AE2 and AE3, respectively. The emissive layers EL1, EL2 and EL3 may be organic emissive layers formed of organic materials and may be formed on the pixel electrodes AE1, AE2 and AE3 via a deposition process. The emissive layers EL1, EL2 and EL3 may have a multi-layer structure. A hole injection material, a hole transport material, a light-emitting material, an electron transport material and/or an electron injection material each may form a layer. In an example in which the thin-film transistor TFT applies a predetermined voltage to the pixel electrodes AE1, AE2 and AE3 of the light-emitting elements ED1, ED2 and ED3 and the common electrode CE of the light-emitting elements ED1, ED2 and ED3 receives a common voltage or cathode voltage, the holes and electrons may be injected and transported, and the holes and electrons may combine in the emissive layers EL1, EL2 and EL3 to emit light.

The emissive layers EL1, EL2 and EL3 may include a first emissive layer EL1, a second emissive layer EL2, and a third emissive layer EL3 disposed in different emission areas EA1, EA2 and EA3, respectively. The first emissive layer EL1 may be disposed on the first pixel electrode AE1 in the first emission area EA1, the second emissive layer EL2 may be disposed on the second pixel electrode AE2 in the second emission area EA2, and the third emissive layer EL3 may be disposed on the third pixel electrode AE3 in the third emission area EA3. The emissive layers EL1, EL2 and EL3 may emit light of different colors, or one emissive layer EL1, EL2 and EL3 may emit mixed light. According to an embodiment of the present disclosure, the first emissive layer EL1 may emit red light, the second emissive layer EL2 may emit green light, and the third emissive layer EL3 may emit blue light. According to another embodiment, the first emissive layer EL1 may emit yellow light, which is a mixture of red light and green light, and the second emissive layer EL2 may emit blue light. According to yet another embodiment, the first emissive layer EL1 may emit white light, which is a mixture of red light, green light, and blue light.

The emissive layers EL1, EL2 and EL3 may be disposed on the upper surface of the pixel-defining layer PDL. According to an embodiment, the emissive layers EL1, EL2 and EL3 may be partially disposed in the space between the pixel electrodes AE1, AE2 and AE3 and the pixel-defining layer PDL. According to an embodiment, the emissive layers EL1, EL2 and EL3 may be in contact with the pixel definition layer PDL, the residual pattern RP, and the pixel electrodes AE1, AE2 and AE3.

The common electrodes CE1, CE2 and CE3 may be disposed on the emissive layers EL1, EL2 and EL3. The common electrodes CE1, CE2 and CE3 include a transparent conductive material to allow light generated in the emissive layers EL1, EL2 and EL3 to exit. The common electrodes CE1, CE2 and CE3 may receive a common voltage or a low-level voltage. In an example in which the pixel electrodes AE1, AE2 and AE3 receive the voltage equal to the data voltage and the common electrodes CE1, CE2 and CE3 receive the low-level voltage, a potential difference may be formed between the pixel electrodes AE1, AE2 and AE3 and the common electrodes CE1, CE2 and CE3, such that the emissive layers EL1, EL2 and EL3 may emit light.

The common electrodes CE1, CE2 and CE3 may include a first common electrode CE1, a second common electrode CE2 and a third common electrode CE3 disposed in different emission areas EA1, EA2 and EA3, respectively. The first common electrode CE1 may be disposed on the first emissive layer EL1 in the first emission area EA1, the second common electrode CE2 may be disposed on the second emissive layer EL2 in the second emission area EA2, and the third common electrode CE3 may be disposed on the third emissive layer EL3 in the third emission area EA3. The first to third common electrodes CE1, CE2 and CE3 may be spaced apart from one another.

A capping layer (not illustrated) may be disposed on the common electrodes CE1, CE2 and CE3. The capping layer may include an organic or inorganic insulating material and cover the patterns disposed on the light-emitting elements ED1, ED2 and ED3. The capping layer can prevent the light-emitting elements ED1, ED2 and ED3 from being damaged by outside air. According to an embodiment, the capping layer may include an organic material such as, for example, a-NPD, NPB, TPD, m-MTDATA, Alq₃, LiF and/or CuPc, or an inorganic material such as, for example, aluminum oxide, titanium oxide, tantalum oxide, hafnium oxide, zinc oxide, silicon oxide, silicon nitride, and/or silicon oxynitride.

The display device 10 may include a plurality of bank structures BNS disposed on the pixel-defining layer PDL. The bank structures BNS may have a structure in which banks BN1 and BN2 containing different materials are sequentially stacked on each other, may include a plurality of openings including emission areas EA1, EA2 and EA3, and may be arranged to overlap with a light-blocking area of the color filter layer CFL, which will be described later. The light-emitting elements ED1, ED2 and ED3 of the display device 10 may be in line with the openings of the bank structure BNS.

A first bank BN1 may be disposed on the pixel-defining layer PDL. A side surface of the first bank BN1 may be recessed more than a side surface of the pixel-defining layer PDL away from the emission areas EA1, EA2 and EA3. The side surface of the first bank BN1 may be recessed more than the second bank BN2 away from the emission areas EA1, EA2 and EA3, which will be described later.

According to an embodiment, the first bank BN1 may include a conductive metal material. According to an embodiment, the first bank BN1 may include aluminum (Al), an oxide of aluminum (Al), or an alloy of aluminum (Al).

The common electrodes CE1, CE2 and CE3 may be in contact with and electrically connected to the first bank BN1. The common electrodes CE1, CE2 and CE3 spaced apart from one another may be electrically connected with one another through the first bank BN1.

The emissive layers EL1, EL2 and EL3 may be in direct contact with side surfaces of the first bank BN1. The contact area between the common electrodes CE1, CE2 and CE3 and the side surface of the first bank BN1 may be greater than the contact area between the emissive layers EL1, EL2 EL3 and the side surface of the first bank BN1. The common electrodes CE1, CE2 and CE3 on the side surface of the first bank BN1 may have a larger area or may be disposed at a higher position on the side surface of the first bank BN1 than the emissive layers EL1, EL2 and EL3. The common electrodes CE1, CE2 and CE3 of different light-emitting elements ED1, ED2 and ED3 are electrically connected through the first bank BN1, and as described herein, embodiments of the present disclosure provide advantages of an increased contact area between the common electrodes CE1, CE2 and CE3 and the first bank BN1.

The first bank BN1 may have an upper surface higher than the common electrodes CE1, CE2 and CE3. The height from the substrate SUB to the upper surface of the first bank BN1 may be greater than the height from the substrate SUB to the common electrodes CE1, CE2 and CE3.

The second bank BN2 may be disposed on the first bank BN1. Referring to FIGS. 4 and 5, the second bank BN2 may include openings in line with the emission areas EA1, EA2 and EA3, respectively, and each of the openings may include a side surface. The second bank BN2 may include tip or eaves, which protrude from the first bank BN1. A side surface of the second bank BN2 may protrude toward the emission areas EA1, EA2 and EA3 more than a side surface of the first bank BN1.

As the side surface of the second bank BN2 protrudes toward the emission areas EA1, EA2 and EA3 more than the side surface of the first bank BN1, an undercut structure of the first bank BN1 may be formed below the tip TIP of the second bank BN2.

In the display device 10 according to the embodiment, the bank structure BNS includes protruding tips TIP toward the emission areas EA1, EA2 and EA3, and thus the emissive layers EL1, EL2 and EL3 and common electrodes CE1, CE2 and CE3 spaced apart from one another may be formed via deposition and etching processes rather than a mask process. In some aspects, embodiments of the present disclosure support forming different layers individually in different emission areas EA1, EA2 and EA3 via a deposition process. For example, even though the emissive layers EL1, EL2 and EL3 and the common electrodes CE1, CE2 and CE3 of the light-emitting elements ED1, ED2 and ED3 are formed via a deposition process without using a mask, the deposited materials may not be connected between the emission areas EA1, EA2 and EA3 but may be disconnected by the tips TIP of the second bank BN2 with the bank structure BNS therebetween. By forming a material for forming a certain layer on the front surface of the display device 10, and then etching and removing a layer formed at an unwanted location, embodiments of the present disclosure support forming different layers individually in different emission areas EA1, EA2 and EA3. In the display device 10, embodiments of the present disclosure support eliminating unnecessary elements and reducing the area of the non-display area NDA.

The second bank BN2 may include a metal material different from the metal material of the first bank BN1. According to an embodiment of the present disclosure, the second bank BN2 may include titanium-zinc (TiZn). Titanium-zinc (TiZn) may be an alloy and may be amorphous.

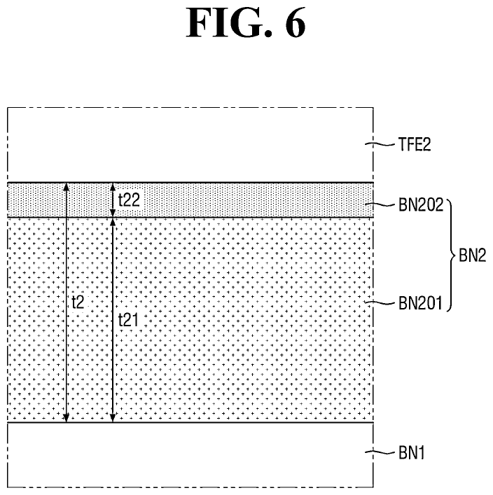

FIG. 6 is an enlarged cross-sectional view of area A2 of FIG. 5, illustrating the cross-section of the second bank BN2 in detail.

The second bank BN2 may include a metal layer BN201 disposed on the first bank BN1 and a metal oxide layer BN202 disposed on the metal layer BN201. According to an embodiment, the metal layer BN201 may include an alloy of titanium-zinc (TiZn), and the metal oxide layer BN202 may include an oxide of titanium-zinc (TiZn).

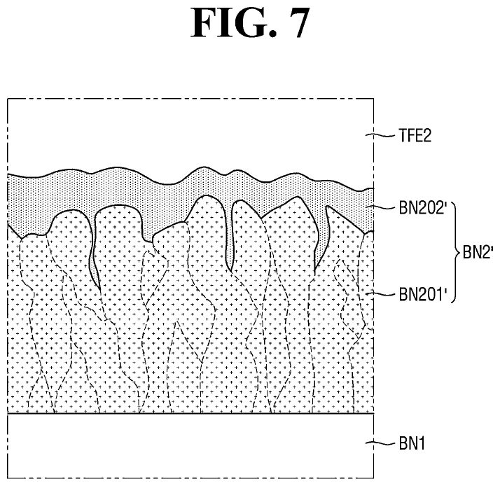

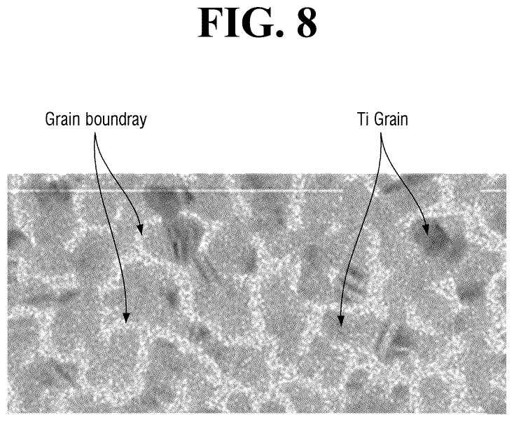

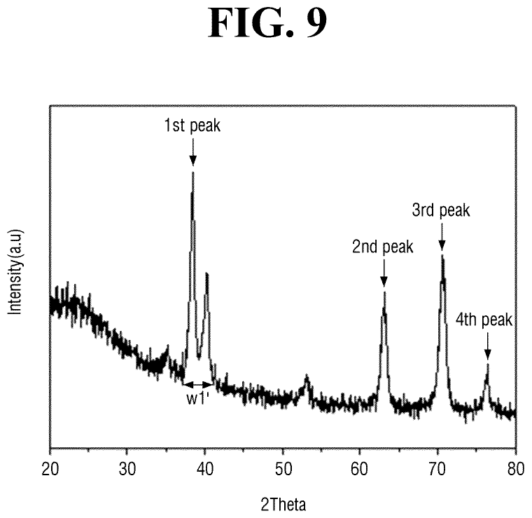

FIG. 7 is a cross-sectional view of an example where a second bank BN2′ contains pure titanium (Ti) as a metallic material rather than an alloy. In an example in which the second bank BN2′ contains pure titanium (Ti), the thickness of the second bank BN2′ increases, titanium (Ti) is crystallized, and the size of the grains in the direction of the crystal plane (111) increases. FIG. 8 is a view illustrating the second bank BN2′ containing crystalline titanium as illustrated in FIG. 7 using a scanning probe microscope (AFM). It can be seen that grains and grain boundaries of titanium (Ti) are observed, and that the surface roughness is high. FIG. 9 is a graph illustrating the second bank containing crystalline titanium (Ti) observed using X-ray diffraction spectroscopy (XRD). It can be seen from FIG. 9 that there are many narrow peaks, which means that the second bank BN2′ of titanium (Ti) is crystalline. The growth of grains may result in non-uniform thickness and high roughness of the titanium layer BN201′, as illustrated in FIG. 7. It is to be understood that characteristics described herein with respect to relative terms of degree such as, for example, “high,” “low,” “large,” “small,” and the like refer to the characteristics satisfying (e.g., being greater than, less than, or the like) a threshold associated with the characteristics.

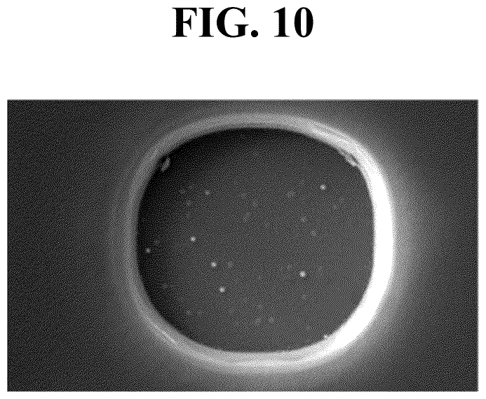

The titanium layer BN201′ reacts with the atmosphere or oxygen gas in the chamber, such that a titanium oxide layer BN202′ of titanium (Ti) is formed on the titanium layer BN201′. The chamber refers to a process chamber that manufactures a second bank layer. For example, a sputtering process chamber. Part of the titanium oxide layer BN202′ may permeate between the grains of titanium (Ti) and into the grain boundaries, and thus the thickness of the titanium oxide layer BN202′ is non-uniform. The titanium oxide layer BN202′ of non-uniform thickness has an undesirable selectivity for a dry etching process and may act as a mask, disturbing etching of the underlying first bank BN1. If the titanium oxide layer BN202′ in the grain boundaries is located inside the emission areas EA1, EA2 and EA3, the first bank BN1 and the second bank BN2 of the emission areas EA1, EA2 and EA3 may not be completely removed and may become a dark spot. FIG. 10 is an image illustrating a comparative example where the second bank BN2′ containing crystalline titanium was not removed from the emission areas EA1, EA2 and EA3, observed using a scanning electron microscope (SEM). It can be seen that there are small residues of the banks BN1 and BN2′ in the emission areas EA1, EA2 and EA3. These may become dark spots when light is emitted.

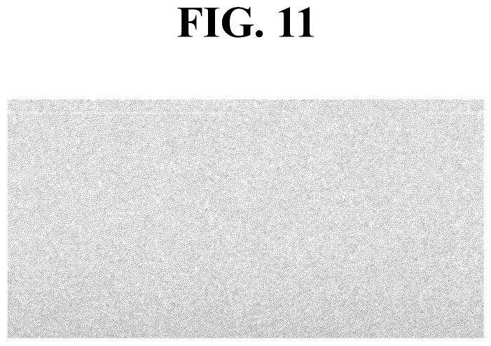

In contrast, when the second bank BN2 contains amorphous titanium-zinc (TiZn) in accordance with one or more embodiments of the present disclosure, there may be no grain boundaries. FIG. 11 is a view illustrating the second bank BN2 of the display device 10 according to an embodiment observed using a scanning probe microscope (AFM). It can be seen that the metal layer BN201 of the second bank BN2 containing titanium-zinc (TiZn) includes no grain boundaries and has low roughness.

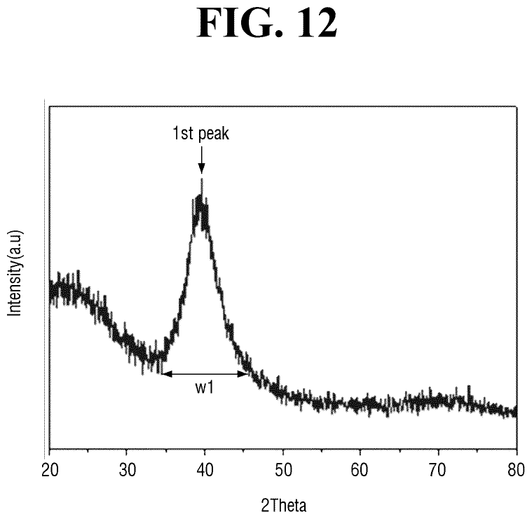

FIG. 12 is a graph illustrating the second bank BN2 of the display device 10 according to an embodiment, observed using X-ray diffraction spectroscopy (XRD). The X-ray diffraction spectroscopy (XRD) spectrum may be measured by scanning a sample in θ/2θ (theta-2theta) mode in an XRD equipment. A Philips X'Pert Pro diffractometer available from Malvern PANalytical Ltd. was employed as the XRD equipment. The intensity is calculated using Bragg's law.

According to an embodiment of the present disclosure, the second bank BN2 and the metal layer BN201 may be amorphous. In an X-ray diffraction spectroscopy (XRD) spectrum, the second bank BN2 and the metal layer BN201 may have one or two peaks which are included in a 2θ (2theta) range from 0° to 80° and are of a relatively broad width. In the XRD graph, a peak width may refer to a difference in 2theta values between points having respective peak values equal to a peak value at a point where a surge in intensity begins immediately before the peak, or a point where the slope of intensity changes from negative to positive immediately before the peak.

Compared to the XRD spectrum in FIG. 9, the XRD spectrum in FIG. 12 has a very large peak width w1 that appears around 40°. The peak width w1′ in FIG. 9 is approximately 5°, while the peak width w1 in FIG. 12 may be ksa ksa1090US° or more or 9° or more. In some aspects, a plurality of peaks appears in the 2theta range of approximately 60° to 80° in the XRD spectrum of FIG. 9, while no peaks appear in the 2theta range of approximately 60° to 80° in the XRD spectrum of FIG. 12. It can be seen that the metal layer BN201 of the second bank BN2 containing titanium-zinc (TiZn) is amorphous.

Referring to FIG. 6, the thickness t21 of the amorphous metal layer BN201 may be constant. The metal oxide layer BN202 formed on the metal layer BN201 may also have a certain thickness t22. In an example, the metal oxide layer BN202 has a uniform thickness t22 and may have an advantageous selectivity for dry etching, and the banks BN1 and BN2 can be completely removed in the emission areas EA1, EA2 and EA3. As a result, no dark spots may occur in the emission areas EA1, EA2 and EA3.

According to an embodiment of the present disclosure, the thickness t22 of the metal oxide layer BN202 of the second bank BN2 may range from 10 Å to 60 Å or 20 Å to 40 Å. The thickness t22 of the metal oxide layer BN202 of the second bank BN2 may range from 1% to 10%, or 1.5% to 6% of the total thickness t2 of the second bank BN2. With the above range regarding the thickness t22, dry etching of the second bank BN2 may not be disturbed. According to an embodiment of the present disclosure, the thickness t2 of the second bank BN2 may range from 500 Å to 2,000 Å. With the above range regarding the thickness t2, the tip of the second bank BN2 can have a small thickness without being bent.

According to an embodiment of the present disclosure, the ratio of zinc (Zn) relative to the total number of atoms included in the metal layer BN201 of the second bank BN2 may range from 20 at % to 60 at %, or 30 at % to 50 at %. With the above range regarding the ratio, embodiments of the present disclosure may prevent crystallization of titanium (Ti), and the second bank BN2 may have amorphous characteristics. Elemental ratios or atomic ratios may be obtained by TEM, EDX or XPS composition analysis.

According to an embodiment of the present disclosure, the roughness of the second bank BN2 may be greater than zero and equal to or less than 1 nm. With the above range regarding the roughness, the second bank BN2 may be removed during dry etching, and the etching of the lower first bank BN1 may not be affected. The roughness of the second bank BN2 may be the roughness of the metal layer BN201 of the second bank BN2. The degree of roughness may be calculated using, for example, the Roughness Average (Ra), the Root Mean Square (RMS) Roughness (Rq), the Maximum Height of the Profile (Rs), and the Ten Point Height (Rz), and other suitable parameters. According to the embodiment of the present disclosure, a value using the Root Mean Square (RMS) Roughness (Rq) may be used as the roughness value. The roughness values may be measured in accordance with ISO 8503 and ASTM D4417.

The tips TIP of the second bank BN2 may overlap with the common electrodes CE1, CE2 and CE3, the emissive layers EL1, EL2 and EL3, and the pixel-defining layer PDL in the direction DR3 perpendicular to the substrate SUB (e.g., in a plan view). For example, the tips TIP of the second bank BN2 may be above the common electrodes CE1, CE2 and CE3, the emissive layers EL1, EL2 and EL3, and the pixel-defining layer PDL in the direction DR3 perpendicular to the substrate SUB. The common electrodes CE1, CE2 and CE3 may be formed below the lower surface of the tips TIP of the second bank BN2. One end and the opposite end of each of the common electrodes CE1, CE2 and CE3 may overlap with the second bank BN2 in the thickness direction DR3 of the substrate.

The thin-film encapsulation layer TFEL may be disposed on the light-emitting elements ED1, ED2 and ED3 and the bank structure BNS, and may cover the plurality of light-emitting elements ED1, ED2 and ED3 and the bank structure BNS. The thin-film encapsulation layer TFEL may include at least one inorganic layer to prevent permeation of oxygen or moisture into the emission material layer EML. The thin-film encapsulation layer TFEL may include at least one organic layer to protect the emission material layer EML from foreign substances such as, for example, dust.

According to embodiments of the present disclosure, the thin-film encapsulation layer TFEL may include a lower inorganic encapsulation film TFE1, an organic encapsulation film TFE2 and an upper inorganic encapsulation film TFE3 stacked on one another in this order.

Each of the lower encapsulation layer TFEL and the upper encapsulation layer TFE3 may include one or more inorganic insulating materials. The inorganic insulating material may be one of silicon oxide, silicon nitride, and silicon oxynitride. For example, the inorganic insulating material may be aluminum oxide, titanium oxide, tantalum oxide, hafnium oxide, zinc oxide, silicon oxide, silicon nitride, and/or silicon oxynitride.

The organic encapsulation layer TFE2 may include a polymer-based material. The polymer-based material may include an acrylic resin, an epoxy resin, polyimide, polyethylene, or the like. For example, the organic encapsulation layer TFEL2 may include an acrylic resin, such as, for example, polymethyl methacrylate and polyacrylic acid. The organic encapsulation layer TFE2 may be formed by curing a monomer or applying a polymer.

The lower inorganic encapsulation layer TFE1 may be disposed on the light-emitting elements ED1, ED2 and ED3 and the bank structure BNS. The lower inorganic encapsulation layer TFE1 may include a first inorganic layer TL1, a second inorganic layer TL2, and a third inorganic layer TL3 disposed in the different emission areas EA1, EA2 and EA3, respectively. The first inorganic layer TL1, the second inorganic layer TL2 and the third inorganic layer TL3 may include an inorganic insulating material and cover the light-emitting elements ED1, ED2 and ED3, respectively. The first inorganic layer TL1, the second inorganic layer TL2 and the third inorganic layer TL3 can prevent the light-emitting elements ED1, ED2 and ED3 from being damaged by outside air.

Since the lower inorganic encapsulation layer TFE1: TL1, TL2 and TL3 may be formed by chemical vapor deposition (CVD), they may be formed along the steps of the layer on which they are deposited. For example, the first inorganic layer TL1, the second inorganic layer TL2 and the third inorganic layer TL3 may form thin films even under the undercut by the tips of the bank structure BNS. The lower inorganic encapsulation layers TL1, TL2 and TL3 may be disposed along the upper, side and lower surfaces of the second bank BN2, the side surfaces of the first bank BN1, and the upper surfaces of the common electrodes CE1, CE2 and CE3. The lower inorganic encapsulation layers TL1, TL2 and TL3 are in contact with the lower surface of the second bank BN2, and can prevent permeation of moisture from the outside air.

The first inorganic layer TL1 may be disposed on (e.g., only on) the first light-emitting element ED1 and the surrounding bank structure BNS, without overlapping the second light-emitting element ED2 or the third light-emitting element ED3. The second inorganic layer TL2 may be disposed on (e.g., only on) the second light-emitting element ED2 and the surrounding bank structure BNS, without overlapping the first light-emitting element ED1 or the third light-emitting element ED3. The third inorganic layer TL3 may be disposed on (e.g., only on) the third light-emitting element ED3 and the surrounding bank structure BNS, without overlapping the first light-emitting element ED1 or the second light-emitting element ED2.

The first inorganic layer TL1 may be formed after the first common electrode CE1 is formed, the second inorganic layer TL2 may be formed after the second common electrode CE2 is formed, and the third inorganic layer TL3 may be formed after the third common electrode CE3 is formed. The first inorganic layer TL1, the second inorganic layer TL2 and the third inorganic layer TL3 may be spaced apart from each other on the bank structure BNS.

The lower inorganic encapsulation layers TL1, TL2 and TL3 may be disposed on the light-emitting elements ED1, ED2 and ED and the upper and lower surfaces of the surrounding second bank BN2 and may be spaced apart from the upper surface of the second bank BN2. That is to say, the lower inorganic encapsulation layers TL1, TL2 and TL3 may have an undercut structure on the second bank BN2. The space between the lower inorganic encapsulation layers TL1, TL2 and TL3 and the second bank BN2 may be created as the materials of the emissive layers EL1, EL2 and EL3 and the common electrodes CE1, CE2 and CE3 have been removed.

The organic encapsulation layer TFE2 may be disposed on the second bank BN2 and the lower inorganic encapsulation layers TL1, TL2 and TL3. A portion of the organic encapsulation layer TFE2 may be disposed in the space between the lower inorganic encapsulation layers TL1, TL2 and TL3 and the upper surface of the second bank BN2. The second bank BN2, the organic encapsulation layer TFE2 and the lower inorganic encapsulation layer TL1, TL2 and TL3 may be sequentially disposed where the second bank BN2 and the lower inorganic encapsulation layer TL1, TL2 and TL3 overlap one another. In tip areas, the organic encapsulation layer TFE2 and the lower inorganic encapsulation layers TL1, TL2 and TL3 may be sequentially disposed on the second bank BN2, and the organic encapsulation layer TFE2 may be disposed over the lower inorganic can TL1, TL2 and TL3 again. In other words, some parts of the organic encapsulation layer TFE2 may be disposed on the upper surface of the second bank BN2 and between the lower inorganic encapsulation layers TL1, TL2 and TL3 on the tips TIP of the second bank BN2, and other portions of the organic encapsulation layer TFE2 may be disposed over the lower inorganic encapsulation layers TL1, TL2 and TL3.

According to the embodiment of the present disclosure, the entire upper surface of the second bank BN2 may be in contact with the organic encapsulation layer TFE2. A first lower surface of the lower inorganic encapsulation layers TL1, TL2 and TL3 may be a surface facing the upper surface of the second bank BN2. A first lower surface of the lower inorganic encapsulation layers TL1, TL2 and TL3 may be in contact with the organic encapsulation layer TFE2. The organic encapsulation layer TFE2 may be in contact with the side surfaces of the second bank BN2.

The upper inorganic encapsulation layer TFE3 may be disposed on the organic encapsulation layer TFE2. The upper inorganic encapsulation layer TFE3 may include aluminum oxide, titanium oxide, tantalum oxide, hafnium oxide, zinc oxide, silicon oxide, silicon nitride, and/or silicon oxynitride.

The display device 10 may include a plurality of color filters CF1, CF2 and CF3 disposed on the emission areas EA1, EA2 and EA3. Each of the plurality of color filters CF1, CF2 and CF3 may include a filtering pattern area and a light-blocking area. The filtering pattern area may be formed in line with the emission areas EA1, EA2 and EA3 or the openings of the bank structures BNS, and may form a light exit area through which light emitted from the emission areas EA1, EA2 and EA3 exits. In the light-blocking area, the color filters CF1, CF2 and CF3 are stacked on one another and thus light cannot pass through the light-blocking area.

The color filters CF1, CF2 and CF3 include a first color filter CF1, a second color filter CF2 and a third color filter CF3 associated with the different emission areas EA1, EA2 and EA3, respectively. The color filters CF1, CF2 and CF3 may include a colorant such as, for example, a dye and pigment that absorbs light in wavelength ranges other than light in a particular wavelength range, and may be disposed in association with the light exiting from the emission areas EA1, EA2 and EA3. For example, the first color filter CF1 may be a red color filter that is disposed such that the first color filter CF1 overlaps with the first emission area EA1 and transmits only first red light. The second color filter CF2 may be a green color filter that is disposed such that the second color filter CF2 overlaps with the second emission area EA2 and transmits only green second light. The third color filter CF3 may be a blue color filter that is disposed such that the third color filter CF3 overlaps with the third emission area EA3 and transmits only blue third light.

In the display device 10, as the color filters CF1, CF2 and CF3 overlap one another, the intensity of reflected light caused by external light can be reduced. Furthermore, the colors of reflected light by external light can be controlled by adjusting the arrangement, shape and area of the color filters CF1, CF2 and CF3 when viewed from the top.

An overcoat layer OC may be disposed on the color filters CF1, CF2 and CF3 and provide flat upper ends of the color filters CF1, CF2 and CF3. The overcoat layer OC may be a colorless light-transmitting layer having no color in the visible light band. For example, the overcoat layer OC may include a colorless light-transmitting organic material such as, for example, an acryl-based resin.

Embodiments of the present disclosure support one or more processes (methods, flowcharts) supportive of the features and embodiments described herein. Descriptions that an element “may be disposed,” “may be formed,” and the like include processes (methods, flowcharts) and techniques for manufacturing, disposing, forming, positioning, and modifying the element and the like in accordance with example aspects described herein.

Although the embodiments of the present disclosure have been described with reference to the accompanying drawings, those skilled in the art would understand that various modifications and alterations may be made without departing from the technical idea or essential features of the present disclosure. Therefore, it should be understood that the above-mentioned embodiments are not limiting but illustrative in all aspects.

What is claimed is:

1. A display device comprising:
a pixel electrode disposed on a substrate;
a pixel-defining layer disposed on the substrate and exposing the pixel electrode;
an emissive layer disposed on the pixel electrode;
a common electrode disposed on the emissive layer;
a first bank disposed on the pixel-defining layer; and
a second bank disposed on the first bank and comprising a side surface protruding more than a side surface of the first bank,
wherein the second bank comprises titanium-zinc (TiZn).

2. The display device of claim 1, wherein the second bank is amorphous.

3. The display device of claim 1, wherein a roughness of the second bank is equal to or less than 1 nm.

4. The display device of claim 1, wherein a peak width of the second bank is 7° or more in an X-ray diffraction spectroscopy (XRD) spectrum.

5. The display device of claim 1, wherein the second bank comprises:
a metal layer disposed on the first bank and comprising titanium-zinc (TiZn); and
a metal oxide layer disposed on the metal layer.

6. The display device of claim 5, wherein the metal oxide layer comprises an oxide of titanium-zinc (TiZn).

7. The display device of claim 5, wherein a thickness of the metal oxide layer ranges from 1% to 10% of an overall thickness of the second bank.

8. The display device of claim 5, wherein the thickness of the metal oxide layer of the second bank is constant.

9. The display device of claim 1, wherein a thickness of the second bank ranges from 500 Å to 1,500 Å.

10. The display device of claim 5, wherein a ratio of zinc (Zn) relative to a total number of atoms in the metal layer of the second bank ranges from 20 at % to 60 at %.

11. The display device of claim 1, further comprising:
a residual pattern disposed between the first pixel electrode and the pixel-defining layer.

12. The display device of claim 1, further comprising:
a lower inorganic encapsulation layer disposed on the common electrode and the second bank and spaced apart from an upper surface of the second bank.

13. The display device of claim 12, further comprising:
an organic encapsulation layer disposed between the upper surface of the second bank and the lower inorganic encapsulation layer.

14. The display device of claim 1, wherein an end of the common electrode is in contact with the side surface of the first bank, and an opposite end of the common electrode is in contact with another side surface of the first bank.

15. A display device comprising:
a pixel electrode disposed on a substrate;
a pixel-defining layer disposed on the substrate and exposing the pixel electrode;
an emissive layer disposed on the pixel electrode;
a common electrode disposed on the emissive layer;
a first bank disposed on the pixel-defining layer; and
a second bank disposed on the first bank and comprising a side surface protruding more than a side surface of the first bank,
wherein in an X-ray diffraction spectroscopy (XRD) spectrum, the second bank comprises one or two peaks in a 2θ (2theta) range from 0° to 80°.

16. The display device of claim 15, wherein a peak width associated with the second bank is 7° or more in an X-ray diffraction spectroscopy (XRD) spectrum.

17. The display device of claim 15, wherein a roughness of the second bank is equal to or less than 1 nm.

18. A display device comprising:
a pixel electrode disposed on a substrate;
a pixel-defining layer disposed on the substrate and exposing the pixel electrode;
an emissive layer disposed on the pixel electrode;
a common electrode disposed on the emissive layer;
a first bank disposed on the pixel-defining layer; and
a second bank disposed on the first bank and comprising a side surface protruding more than a side surface of the first bank,
wherein the second bank comprises:
a metal layer disposed on the first bank and comprising titanium-zinc (TiZn), and
a metal oxide layer disposed on the metal layer and comprising an oxide of titanium-zinc (TiZn), and
wherein a thickness of the metal oxide layer ranges from 1% to 10% of a total thickness of the second bank.

19. The display device of claim 18, wherein the total thickness of the second bank ranges from 500 Å to 1,500 Å.

20. The display device of claim 18, wherein a ratio of zinc (Zn) relative to a total number of atoms in the metal layer of the second bank ranges from 20 at % to 60 at %.
